(19) United States
(12) Patent Application Publication
(10) Pub. No.: US 2013/0164676 A1
(43) Pub. Date: Jun. 27, 2013

(54) CARBAMOYLOXYADAMANTANE DERIVATIVE, POLYMER COMPOUND, AND PHOTORESIST COMPOSITION

(71) Applicants: Takashi Fukumoto, Niigata (JP); Manabu Yada, Niigata (JP)

(72) Inventors: Takashi Fukumoto, Niigata (JP); Manabu Yada, Niigata (JP)

(73) Assignee: KURARAY CO., LTD., Kurashiki-shi (JP)

(21) Appl. No.: 13/822,036

(22) PCT Filed: Aug. 25, 2011
(86) PCT No.: PCT/JP2011/069212

§ 371 Date: Mar. 11, 2013

(30) Foreign Application Priority Data
Sep. 14, 2010 (JP) 2010-206153

(51) Int. Cl. G03F 7/027

(52) U.S. Cl. CPC G03F 7/027
USPC 430/270.1; 560/162; 526/281

(57) ABSTRACT

To provide a novel acrylic ester derivative which can form a structural unit of a polymer to be incorporated into a photoresist composition, a polymer produced through polymerization of a raw material containing the acrylic ester derivative, and a photoresist composition which contains the polymer and which, as compared with the case of conventional ones, realizes formation of a high-resolution resist pattern having improved LWR. The invention provides a carbamoyloxyadamantane derivative represented by the following formula (wherein R represents a hydrogen atom, a methyl group, or a trifluoromethyl group), a polymer produced by polymerizing a raw material containing the carbamoyloxyadamantane derivative, and a photoresist composition containing the polymer, a photoacid generator, and a solvent.

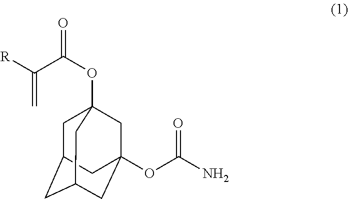

### FIELD OF THE INVENTION

The present invention relates to a carbamoyloxyadamantane derivative; a polymer produced through polymerization of a raw material containing the carbamoyloxyadamantane derivative; and a photoresist composition which realizes formation of a high-resolution resist pattern having improved line width roughness (LWR).

### BACKGROUND ART

Lithography involves a process in which, for example, a resist film is formed from a resist material on, a substrate; the resist film is subjected to selective light exposure to a radiation such as light or electron beam via a mask having a specific pattern; and the exposed resist film is developed, to thereby form a specific resist pattern on the film. As used herein, the term “positive tone resist material” refers to a resist material which, when exposed to light, dissolves in a developer, and the term “negative tone resist material” refers to a resist material which, when exposed to light, does not dissolve in a developer.

In recent years, with the progress of lithography techniques, micro-patterning has been rapidly developed in production of semiconductor devices or liquid crystal display devices. Generally, miniaturization of patterning is carried out by use of an exposure light source of short wavelength (higher energy). Hitherto, ultraviolet rays such as g-ray and i-ray have been used for lithography. Recently, KrF excimer laser or ArF excimer laser has been used for mass production of semiconductor devices. Also, attempts have been made to use, in lithography, F₂ excimer laser, electron beams, EUVs (extreme ultraviolet rays), X-rays, etc., having a shorter wavelength (higher energy) as compared with KrF excimer laser or ArF excimer laser.

A resist material is required to exhibit various lithographic properties, including sensitivity to such an exposure light source, and resolution which realizes reproduction of micro-patterning.

A resist material satisfying these requirements is, for example, a chemically amplified resist composition containing a base component whose solubility in an alkaline developer changes through the action of an acid, and an acid generator component which generates an acid through light exposure.

For example, a generally used chemically amplified positive tone resist composition contains a resin component (base resin) whose solubility in an alkaline developer increases through the action of an acid, and an acid generator component. In the case where a resist film is formed from such a resist composition, when the resist film is subjected to selective light exposure during formation of a resist pattern, an acid is generated from the acid generator at an exposed portion of the film, and the solubility of the resin in an alkaline developer increases through the action of the acid, whereby the exposed portion becomes soluble in the alkaline developer.

A photoresist composition which is currently used for, for example, ArF excimer laser lithography generally contains, as a base resin, a resin having a main chain formed of a structural unit derived from a (meth)acrylic acid ester; i.e., an acrylic resin, since the resin exhibits excellent transparency at 193 nm or thereabout (see, for example, Patent Document 1).

There has also been proposed, incorporation of a nitrogen-containing organic compound such as an alkylamine or an alkylalcoholamine in a chemically amplified resist composition containing a base resin and an acid generator. The nitrogen-containing organic compound serves as a quencher which traps acid generated from the acid generator, whereby lithographic properties such as the shape of a resist pattern can be improved. Generally, tertiary amines are widely used as the nitrogen-containing organic compounds. In a trend for forming micro-resist patterns, a variety of nitrogen-containing organic compounds are employed in order to improve process margin during formation of isolated patterns and other properties (see, for example, Patent Documents 2 and 3).

### PRIOR ART DOCUMENT

### Patent Document

Patent Document 1: Japanese Patent Application Laid-Open (kokai) No. 2003-241385
Patent Document 2: Japanese Patent Application Laid-Open (kokai) No. 2001-166476
Patent Document 3: Japanese Patent Application Laid-Open (kokai) No. 2001-215689

### SUMMARY OF THE INVENTION

### Problems to be Solved by the Invention

However, the aforementioned photoresist compositions containing a tertiary amine as a nitrogen-containing organic compound have problems of low storage stability and impaired lithographic properties, although the photoresist compositions realize suppression of acid diffusion from an exposed area to an unexposed area and have excellent resistance to environmental conditions. This is because the tertiary amine reacts with ester moieties of the acid generator or the base component in the photoresist compositions to cause decomposition thereof because of its excessively high nucleophilic property and basicity. Also, the photoresist compositions disclosed in Patent Documents 2 and 3 containing a nitrogen-containing organic compound do not provide satisfactory lithographic properties and pattern shape which are required in a trend for micro-patterning.

Since, in the future, lithographic technology is expected to be developed, and application of such technology is expected to increases, there is demand for the development of a novel material which can be employed in lithography. For example, as the resist pattern becomes finer, keen demand has arisen for development of a resist material which realizes further improved lithographic properties, including resolution and line width roughness (LWR), as well as further improved patterning. Therefore, it is important to develop a novel (meth)acrylic ester derivative which can form a structural unit of a polymer to be incorporated into a photoresist composition.

In view of the foregoing, an object of the present invention is to provide a novel (meth)acrylic ester derivative which can form a structural unit of a polymer to be incorporated into a photoresist composition. Another object of the present invention is to provide a polymer produced through polymerization of a raw material containing the (meth)acrylic ester derivative. Yet another object of the present invention is to provide a photoresist composition which contains the polymer and which, as compared with the case of conventional ones, realizes formation of a high-resolution resist pattern having improved LWR.

### Means for Solving the Problems

The present inventors have conducted extensive studies, and have found that, when a photoresist composition containing a polymer which is produced by polymerizing a raw material containing an acrylic ester derivative having an adamantyl group bearing a carbamoyloxy group as a substituent at a specific position realizes formation of a high-resolution resist pattern having improved LWR, as compared with the case of conventional photoresist compositions.

Accordingly, the present invention provides the following [1] to [3].

[1] A carbamoyloxyadamantane derivative represented by the following formula (1):

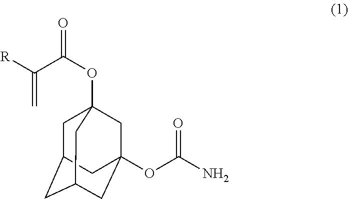

wherein R represents a hydrogen atom, a methyl group, or a trifluoromethyl group.
[2] A polymer produced by polymerizing a raw material containing a carbamoyloxyadamantane derivative as recited in [1] above.
[3] A photoresist composition comprising a polymer as recited in [2] above, a photoacid generator, and a solvent.

### Effects of the Invention

A photoresist composition containing the polymer which is produced by polymerizing a raw material containing the carbamoyloxyadamantane derivative of the present invention realizes formation of a high-resolution resist pattern having improved LWR by diffusion of an acid generated from a photoacid generator during light exposure can be suppressed.

### MODES FOR CARRYING OUT THE INVENTION

### [Carbamoyloxyadamantane Derivative (1)]

For producing a photoresist composition which can realize suppression of diffusion of an acid generated from a photoacid generator during light exposure, to thereby improve LWR, a carbamoyloxyadamantane derivative represented by the following formula (1) (hereinafter referred to as carbamoyloxyadamantane derivative (1)) is suitably employed.

A characteristic feature of the carbamoyloxyadamantane derivative (1) resides in that the derivative has an adamantyl group bearing a carbamoyloxy group as a substituent at a specific position. When a photoresist composition containing a polymer which is produced by polymerizing a raw material containing the carbamoyloxyadamantane derivative (1) realizes formation of a high-resolution resist pattern having improved LWR.

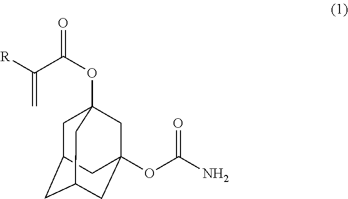

In the aforementioned carbamoyloxyadamantane derivative (1), R represents a hydrogen atom, a methyl group, or a trifluoromethyl group. Of these, R is preferably a hydrogen atom or a methyl group.

### (Method for Producing Carbamoyloxyadamantane Derivative (1))

No particular limitation is imposed on the method for producing the carbamoyloxyadamantane derivative (1) of the present invention. However, the following production method including the following first and second steps may be employed.

First step: Production process of a chlorosulfonyl derivative (hereinafter referred to as chlorosulfonyl derivative (3)) by reaction of a hydroxyadamantane derivative (hereinafter referred to as hydroxyadamantane derivative (2)) with chlorosulfonyl isocyanate.

Second step: Production process of the carbamoyloxyadamantane derivative (1) by reaction of the chlorosulfonyl derivative (3) with water.

With reference to the following reaction scheme including the first and second steps, each step will be described in detail (in the scheme, R has the same meaning as defined above). Note that the aforementioned hydroxyadamantane derivative (2) and the chlorosulfonyl derivative (3) have the structures as shown in the scheme.

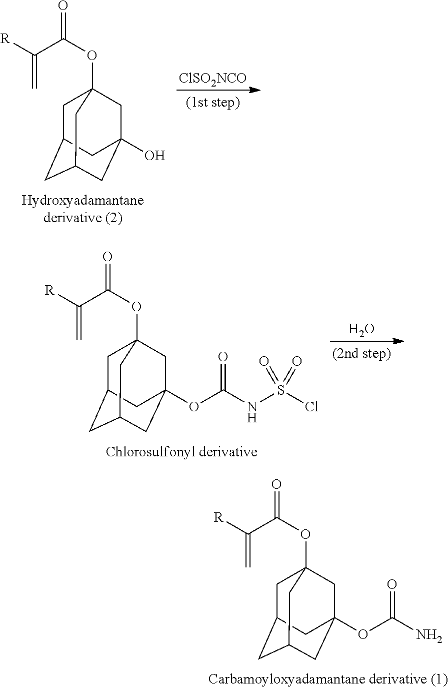

### (First Step)

In the first step, the hydroxyadamantane derivative (2) is reacted with chlorosulfonyl isocyanate, to thereby produce the chlorosulfonyl derivative (3).

Specific examples of the hydroxyadamantane derivative (2) include 3-hydroxyadamantan-1-yl acrylate, 3-hydroxyadamantan-1-yl methacrylate, and 3′-hydroxyadamantan-1′-yl 2-trifluoromethylacrylate.

The amount of chlorosulfonyl isocyanate used in the reaction is preferably 1 to 3 mol on the basis of 1 mol of the hydroxyadamantane derivative (2), from the viewpoint of facility of post-treatment, more preferably 1 to 2 mol.

The first step is carried out in the presence or absence of solvent. No particular limitation is imposed on the solvent, so long as the solvent does not impair reaction. Examples of the solvent include saturated hydrocarbons such as hexane, heptane, and cyclohexane; aromatic hydrocarbons such as benzene, toluene, and xylene; halogenated hydrocarbons such as methylene chloride, dichloroethane, chloroform, and chlorobenzene; esters such as methyl acetate, ethyl acetate, and propyl acetate; and nitriles such as acetonitrile, propionitrile, and benzonitrile. These members may be used singly or in combination of two or more species. Among these solvents, aromatic hydrocarbons are preferred, with toluene being more preferred.

When the first step is carried out in the presence of solvent, the amount of the solvent used in the first step is preferably 0.5 to 100 parts by mass on the basis of 1 part by mass of the hydroxyadamantane derivative (2), from the viewpoint of facility of post-treatment, more preferably 0.5 to 20 parts by mass.

The reaction temperature employed in the first step, which varies depending on the type of the hydroxyadamantane derivative (2), the type of the solvent, etc., is preferably −30 to 100° C., more preferably −10 to 50° C. No particular limitation is imposed on the reaction pressure, but the first step is generally preferably carried out under atmospheric pressure.

The reaction time employed in the first step, which varies depending on the type and amount of the hydroxyadamantane derivative (2), the type and amount of the solvent, the reaction temperature, etc., is preferably about 1 hour to about 50 hours.

The first step is preferably carried out in an inert gas atmosphere such as nitrogen or argon.

The reaction mixture containing the chlorosulfonyl derivative (3) obtained in the first step may be supplied as a raw material to the second step without performing any particular purification. This mode can be easily realized and is preferred from the viewpoint of production cost.

No particular limitation is imposed on the procedure of the first step. In a preferred embodiment, the hydroxyadamantane derivative (2) and an optional solvent are placed in a reactor, and chlorosulfonyl isocyanate is added dropwise to the mixture at a specific reaction temperature and pressure. The duration of the above addition of chlorosulfonyl isocyanate, which varies in depending on the amount of chlorosulfonyl isocyanate used, is generally preferably 20 minutes to 10 hours, more preferably 30 minutes to 5 hours, still more preferably 30 minutes to 3 hours, for appropriately controlling the reaction temperature. Notably, the reaction time includes the duration of addition.

### (Second Step)

In the second step, the chlorosulfonyl derivative (3) is reacted with water, to thereby produce the carbamoyloxyadamantane derivative (1).

The amount of water used, on the basis of 1 mol of the chlorosulfonyl derivative (3) produced in the first step, is preferably 1 to 100 mol, from the viewpoint of facility of post-treatment, more preferably 1 to 50 mol.

The second step is carried out in the presence or absence of solvent. No particular limitation is imposed on the solvent, so long as the solvent does not impair reaction. Examples of the solvent include those exemplified in relation to the first step. Preferred solvents are the same as those exemplified in relation to the first step. Thus, preferably, the same solvent employed in the first step is also employed in the second step. These solvents may be used singly or in combination of two or more species.

When the second step is carried out in the presence of solvent, the amount of the solvent is preferably 0.5 to 100 parts by mass on the basis of 1 part by mass of the chlorosulfonyl derivative (3), from the viewpoint of facility of post-treatment, more preferably 0.5 to 20 parts by mass. In the case where the reaction mixture produced in the first step is used, without performing any further treatment, as a raw material in the second step, the amount of solvent may be maintained or may be increased so that the amount falls within the aforementioned range.

The reaction temperature employed in the second step, which varies depending on the type of the chlorosulfonyl derivative (3), the type of the solvent, etc., is preferably −30 to 100° C., more preferably −10 to 50° C. No particular limitation is imposed on the reaction pressure, but the second step is generally preferably carried out under atmospheric pressure.

The reaction time employed in the second step, which varies depending on the type and amount of the chlorosulfonyl derivative (3), the type and amount of the solvent, the reaction temperature, etc., is preferably about 1 hour to about 50 hours.

No particular limitation is imposed on the procedure of the second step. In a preferred embodiment, the chlorosulfonyl derivative (3) and an optional solvent are placed in a reactor, and water is added dropwise to the mixture at a specific reaction temperature and pressure. The duration of the above addition of water, which varies in depending on the amount of water used, is generally preferably 20 minutes to 10 hours, more preferably 30 minutes to 5 hours, still more preferably 30 minutes to 2 hours, for appropriately controlling the reaction temperature. Notably, the reaction time includes the duration of addition.

The carbamoyloxyadamantane derivative (1) may be separated from the reaction mixture obtained through the aforementioned method and may be purified through a generally employed organic compound separation/purification method.

In one procedure, a solvent and water are added to the reaction mixture after completion of the second step, and the resultant mixture is allowed to stand, to thereby form an organic layer and an aqueous layer. The organic layer is separated and condensed, to thereby isolate the carbamoyloxyadamantane derivative (1). If required, the product is purified through recrystallization, silica gel column chromatography, etc., to thereby obtain the carbamoyloxyadamantane derivative (1) with high purity.

### [Polymer]

A homopolymer of the carbamoyloxyadamantane derivative (1) of the present invention or a copolymer of the carbamoyloxyadamantane derivative (1) and another polymerizable compound is useful as a polymer for a photoresist composition.

The polymer of the present invention contains a structural unit derived from a carbamoyloxyadamantane derivative (1) in an amount of more than 0 mol % to 100 mol %. The amount of the structural unit is preferably 5 to 80 mol %, more preferably 10 to 70 mol %, much more preferably 10 to 50 mol %, for improvement of LWR and resolution.

Specific examples of the polymerizable compound which can be copolymerized with the carbamoyloxyadamantane derivative (1) (hereinafter the compound may be referred to as “copolymerizable monomer”) include, but are not particularly limited to, compounds represented by the following chemical formulas.

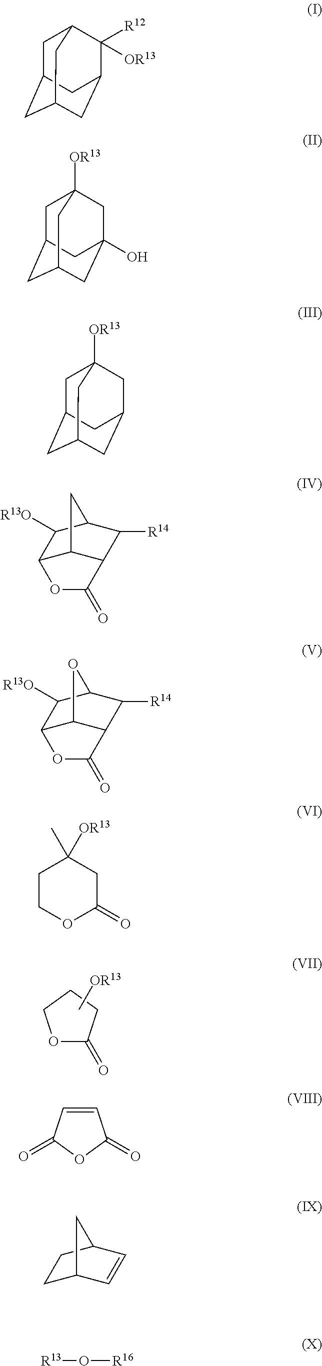

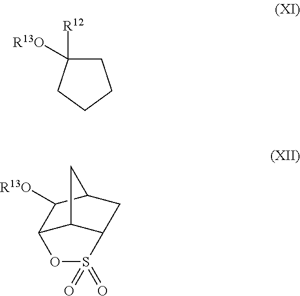

In the aforementioned formulas (I) to (XII), R¹² represents a hydrogen atom or a C1 to C3 alkyl group; R¹³ represents a polymerizable group; R¹⁴ represents a hydrogen atom or —COOR¹⁵; R¹⁵ represents a C1 to C3 alkyl group; and R¹⁶ represents a C₁ to C₁₀ alkyl group.

Examples of the C1 to C3 alkyl group represented by each of R¹² and R¹⁵ in the copolymerizable monomer include methyl, ethyl, n-propyl, and isopropyl. Examples of the alkyl group represented by R¹⁶ include methyl, ethyl, n-propyl, isopropyl, n-butyl, isobutyl, s-butyl, and t-butyl. Examples of the polymerizable group represented by R¹³ include acryloyl, methacryloyl, vinyl, and crotonoyl.

Among the aforementioned copolymerizable monomers, preferred are copolymerizable monomers represented by formulas (I), (II), (IV), or (XII). More preferably, a copolymerizable monomer represented by formula (I) is employed in combination with a copolymerizable monomer represented by formula (II) and a copolymerizable monomer represented by formula (IV), or a copolymerizable monomer represented by formula (I) is employed in combination with a copolymerizable monomer represented by formula (II) and a copolymerizable monomer represented by formula (XII).

### (Production Method for Polymer)

The polymer may be produced through radical polymerization by a customary method. Particularly, a polymer having a small molecular weight distribution is synthesized through, for example, living radical polymerization.

In a general radical polymerization method, optionally one or more carbamoyloxyadamantane derivatives (1) and optionally one or more of the aforementioned copolymerizable monomers are polymerized in the presence of a radical polymerization initiator, a solvent, and optionally a chain transfer agent.

No particular limitation is imposed on the method for carrying out radical polymerization, and radical polymerization may be carried out through a conventional method employed for production of an acrylic resin, such as solution polymerization, emulsion polymerization, suspension polymerization, or bulk polymerization.

Examples of the aforementioned radical polymerization initiator include hydroperoxide compounds such as t-butyl hydroperoxide and cumene hydroperoxide; dialkyl peroxide compounds such as di-t-butyl peroxide, t-butyl-α-cumyl peroxide, and di-α-cumyl peroxide; diacyl peroxide compounds such as benzoyl peroxide and diisobutyryl peroxide; and azo compounds such as 2,2′-azobisisobutyronitrile and dimethyl 2,2′-azobisisobutyrate.

The amount of the radical polymerization initiator employed may be appropriately determined in consideration of polymerization conditions, including the type and amount of carbamoyloxyadamantane derivative (1), copolymerizable monomer, chain transfer agent, and solvent employed for polymerization reaction, and polymerization temperature. Generally, the amount of the radical polymerization initiator is preferably 0.005 to 0.2 mol, more preferably 0.01 to 0.15 mol, on the basis of 1 mol of all the polymerizable compounds [corresponding to the total amount of an carbamoyloxyadamantane derivative (1) and a copolymerizable monomer, the same shall apply hereinafter].

No particular limitation is imposed on the aforementioned solvent, so long as it does not inhibit polymerization reaction. Examples of the solvent include glycol ethers such as propylene glycol monoethyl ether, propylene glycol monomethyl ether acetate, ethylene glycol monomethyl ether, ethylene glycol monomethyl ether acetate, ethylene glycol monomethyl ether propionate, ethylene glycol monobutyl ether, ethylene glycol monobutyl ether acetate, and diethylene glycol dimethyl ether; esters such as ethyl lactate, methyl 3-methoxypropionate, methyl acetate, ethyl acetate, and propyl acetate; ketones such as acetone, methyl ethyl ketone, methyl isopropyl ketone, methyl isobutyl ketone, methyl amyl ketone, cyclopentanone, and cyclohexanone; and ethers such as diethyl ether, diisopropyl ether, dibutyl ether, tetrahydrofuran, and 1,4-dioxane.

Generally, the amount of the solvent employed is preferably 0.5 to 20 parts by mass on the basis of 1 part by mass of all the polymerizable compounds. From the viewpoint of economy, the amount is more preferably 1 to 10 parts by mass.

Examples of the aforementioned chain transfer agent include thiol compounds such as dodecanethiol, mercaptoethanol, mercaptopropanol, mercaptoacetic acid, and mercaptopropionic acid. When a chain transfer agent is employed, generally, the amount thereof is preferably 0.005 to 0.2 mol, more preferably 0.01 to 0.15 mol, on the basis of 1 mol of all the polymerizable compounds.

Generally, the polymerization temperature is preferably 40 to 150° C. The polymerization temperature is more preferably 60 to 120° C., from the viewpoint of the stability of a polymer produced.

The polymerization reaction time may vary with polymerization conditions, including the type and amount of carbamoyloxyadamantane derivative (1), copolymerizable monomer, polymerization initiator, and solvent employed, and polymerization reaction temperature. Generally, the polymerization time is preferably 30 minutes to 48 hours, more preferably 1 hour to 24 hours.

Polymerization reaction is preferably carried out in an atmosphere of an inert gas such as nitrogen or argon.

The thus-produced polymer may be isolated through a common process such as reprecipitation. The thus-isolated polymer may be dried through, for example, vacuum drying.

Examples of the solvent employed for the reprecipitation process include aliphatic hydrocarbons such as pentane and hexane; alicyclic hydrocarbons such as cyclohexane; aromatic hydrocarbons such as benzene and xylene; halogenated hydrocarbons such as methylene chloride, chloroform, chlorobenzene, and dichlorobenzene; nitrated hydrocarbons such as nitromethane; nitriles such as acetonitrile and benzonitrile; ethers such as diethyl ether, diisopropyl ether, tetrahydrofuran, and 1,4-dioxane; ketones such as acetone and methyl ethyl ketone; carboxylic acids such as acetic acid; esters such as ethyl acetate and butyl acetate; carbonates such as dimethyl carbonate, diethyl carbonate, and ethylene carbonate; alcohols such as methanol, ethanol, propanol, isopropyl alcohol, and butanol; and water. These solvents may be employed singly or in combination of two or more species.

The amount of the solvent employed for the reprecipitation process may vary with the type of the polymer or solvent. Generally, the amount of the solvent is preferably 0.5 to 100 parts by mass on the basis of 1 part by mass of the polymer. From the viewpoint of economy, the amount is more preferably 1 to 50 parts by mass.

No particular limitation is imposed on the weight average molecular weight (Mw) of the polymer, but the Mw is preferably 500 to 50,000, more preferably 1,000 to 30,000, much more preferably 5,000 to 15,000. When the Mw falls within the above preferred range, the polymer is highly useful as a component of the below-described photoresist composition. The Mw of the polymer is determined through the method described hereinbelow in the Examples.

No particular limitation is imposed on the molecular weight distribution (Mw/Mn) of the polymer, but it is preferably 1.0 to 3, more preferably 1.0 to 2.0. When the Mw/Mn satisfies the conditions, the polymer serves as a useful component of the photoresist composition. Note that the Mw and the number average molecular weight (Mn) are measured through the method described in the Examples hereinbelow.

### [Photoresist Composition]

The photoresist composition of the present invention is prepared by mixing the aforementioned polymer with a photoacid generator and a solvent, and optionally a basic compound, a surfactant, and an additional additive. The respective components will next be described.

### (Photoacid Generator)

No particular limitation is imposed on the photoacid generator employed, and the photoacid generator may be any known photoacid generator which is generally employed in conventional chemically amplified resists. Examples of the photoacid generator include onium salt photoacid generators such as iodonium salts and sulfonium salts; oxime sulfonate photoacid generators; bisalkyl or bisarylsulfonyldiazomethane photoacid generators; nitrobenzyl sulfonate photoacid generators; iminosulfonate photoacid generators; and disulfone photoacid generators. These photoacid generators may be employed singly or in combination of two or more species. Of these, an onium salt photoacid generator is preferred. More preferred is a fluorine-containing onium salt containing a fluorine-containing alkyl sulfonate ion as an anion, since such an onium salt generates a strong acid.

Specific examples of the aforementioned fluorine-containing onium salt include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate, or nonafluorobutanesulfonate; tri(4-methylphenyl)sulfonium trifluoromethanesulfonate, heptafluoropropanesulfonate, or nonafluorobutanesulfonate; dimethyl(4-hydroxynaphthyl)sulfonium trifluoromethanesulfonate, heptafluoropropanesulfonate, or nonafluorobutanesulfonate; monophenyldimethylsulfonium trifluoromethanesulfonate, heptafluoropropanesulfonate, or nonafluorobutanesulfonate; diphenylmonomethylsulfonium trifluoromethanesulfonate, heptafluoropropanesulfonate, or nonafluorobutanesulfonate; (4-methylphenyl)diphenylsulfonium trifluoromethanesulfonate, heptafluoropropanesulfonate, or nonafluorobutanesulfonate; (4-methoxyphenyl)diphenylsulfonium trifluoromethanesulfonate, heptafluoropropanesulfonate, or nonafluorobutanesulfonate; and tri(4-tert-butyl)phenylsulfonium trifluoromethanesulfonate, heptafluoropropanesulfonate, or nonafluorobutanesulfonate. These onium salts may be employed singly or in combination of two or more species.

Generally, the amount of the photoacid generator incorporated is preferably 0.1 to 30 parts by mass, more preferably 0.5 to 10 parts by mass, on the basis of 100 parts by mass of the aforementioned polymer, in order to secure the sensitivity and developability of the photoresist composition.

### (Solvent)

Examples of the solvent incorporated into the photoresist composition include glycol ethers such as propylene glycol monoethyl ether, propylene glycol monomethyl ether acetate, ethylene glycol monomethyl ether, ethylene glycol monomethyl ether acetate, ethylene glycol monomethyl ether propionate, ethylene glycol monobutyl ether, ethylene glycol monobutyl ether acetate, and diethylene glycol dimethyl ether; esters such as ethyl lactate, methyl 3-methoxypropionate, methyl acetate, ethyl acetate, and propyl acetate; ketones such as acetone, methyl ethyl ketone, methyl isopropyl ketone, methyl isobutyl ketone, methyl amyl ketone, cyclopentanone, and cyclohexanone; and ethers such as diethyl ether, diisopropyl ether, dibutyl ether, tetrahydrofuran, and 1,4-dioxane. These solvents may be employed singly or in combination of two or more species.

Generally, the amount of the solvent incorporated is preferably 1 to 50 parts by mass, more preferably 2 to 25 parts by mass, on the basis of 1 part by mass of the polymer.

### (Basic Compound)

In order to reduce the diffusion rate of an acid in a photoresist film for improvement of resolution, the photoresist composition may optionally contain a basic compound in such an amount that the compound does not impair the properties of the photoresist composition. Examples of the basic compound include amides such as formamide, N-methylformamide, N,N-dimethylformamide, acetamide, N-methylacetamide, N,N-dimethylacetamide, N-(1-adamantyl)acetamide, benzamide, N-acetylethanolamine, 1-acetyl-3-methylpiperidine, pyrrolidone, N-methylpyrrolidone, ε-caprolactam, δ-valerolactam, 2-pyrrolidinone, acrylamide, methacrylamide, t-butylacrylamide, methylenebisacrylamide, methylenebismethacrylamide, N-methylolacrylamide, N-methoxyacrylamide, and diacetoneacrylamide; and amines such as pyridine, 2-methylpyridine, 4-methylpyridine, nicotine, quinoline, acridine, imidazole, 4-methylimidazole, benzimidazole, pyradine, pyrazole, pyrrolidine, N-t-butoxycarbonylpyrrolidine, piperidine, tetrazole, morpholine, 4-methylmorpholine, piperazine, 1,4-diazabicyclo[2.2.2]octane, tributylamine, tripentylamine, trihexylamine, triheptylamine, trioctylamine, and triethanolamine. These basic compounds may be employed singly or in combination of two or more species.

When a basic compound is incorporated, generally, the amount thereof—which may vary with the type of the basic compound—is preferably 0.01 to 10 mol, more preferably 0.05 to 1 mol, on the basis of 1 mol of the photoacid generator.

### (Surfactant)

For improvement of coating properties, the photoresist composition may optionally contain a surfactant in such an amount that the surfactant does not impair the properties of the photoresist composition.

Examples of the surfactant include polyoxyethylene lauryl ether, polyoxyethylene stearyl ether, polyoxyethylene oleyl ether, and polyoxyethylene n-octyl phenyl ether. These surfactants may be employed singly or in combination of two or more species.

When a surfactant is incorporated, generally, the amount thereof is preferably 2 parts by mass or less on the basis of 100 parts by mass of the polymer.

### (Additional Additive)

The photoresist composition may also contain an additional additive such as a sensitizer, a halation-preventing agent, a shape-improving agent, a storage stabilizer, or an antifoaming agent in such an amount that the additive does not impair the properties of the photoresist composition.

### (Photoresist Pattern Formation Method)

A specific resist pattern may be formed through the following procedure: the photoresist composition is coated onto a substrate; the composition-coated substrate is generally prebaked at preferably 70 to 160° C. for 1 to 10 minutes; the resultant product is irradiated with a radiation (exposed to light) via a specific mask; subsequently, post-exposure baking is carried out at preferably 70 to 160° C. for 1 to 5 minutes, to thereby form a latent image pattern; and then development is carried out by use of a developer.

Light exposure may be carried out by means of a radiation of any wavelength; for example, UV rays or X-rays. For the case of a semiconductor resist, g-ray, i-ray, or an excimer laser such as XeCl, KrF, KrCl, ArF, or ArCl is generally employed. Of these, ArF excimer laser is preferably employed, for improvement of micropatterning.

The amount of exposure light is preferably 0.1 to 1,000 mJ/cm², more preferably 1 to 500 mJ/cm².

Examples of the developer include alkaline aqueous solutions prepared by dissolving, in water, inorganic bases such as sodium hydroxide, potassium hydroxide, sodium carbonate, and aqueous ammonia; alkylamines such as ethylamine, diethylamine, and triethylamine; alcoholamines such as dimethylethanolamine and triethanolamine; and quaternary ammonium salts such as tetramethylammonium hydroxide and tetraethylammonium hydroxide. Of these, an alkaline aqueous solution prepared by dissolving, in water, a quaternary ammonium salt such as tetramethylammonium hydroxide or tetraethylammonium hydroxide is preferably employed.

Generally, the developer concentration is 0.1 to 20 mass %, more preferably 0.1 to 10 mass %.

### EXAMPLES

The present invention will next be described in detail by way of Examples, which should not be construed as limiting the invention thereto. Measurement of Mw and Mn and calculation of molecular weight distribution were carried out as described below.

### (Measurement of Mw and Mn, and Calculation of Molecular Weight Distribution)

For measurement of weight average molecular weight (Mw) and number average molecular weight (Mn), gel permeation chromatography (GPC) employing a differential refractometer as a detector and tetrahydrofuran (THF) as an eluent was carried out under the below-described conditions, and a calibration curve prepared by use of standard polystyrene was employed for molecular weight conversion. Molecular weight distribution (Mw/Mn) was determined by dividing weight average molecular weight (Mw) by number average molecular weight (Mn).

By means of a column prepared by connecting “TSK-gel supermultipore HZ-M” (trade name, product of Tosoh Corporation, 4.6 mm×150 mm)×3 in series, GPC measurement was carried out under the following conditions: column temperature: 40° C., differential refractometer temperature: 40° C., and eluent flow rate: 0.35 mL/minute.

### Example 1

### Synthesis of 3-carbamoyloxyadamantan-1-yl methacrylate

### (First Step)

To a four-necked flask having a capacity of 10 L and equipped with a thermometer, a stirrer, a nitrogen conduit, and a dropping funnel, 460.0 g (1.947 mol) of 3-hydroxyadamantan-1-yl methacrylate and 1200 g of toluene were added, and the inside temperature of the flask was lowered to 5° C. The atmosphere of the flask was purged with nitrogen. Subsequently, 303.1 g (2.141 mol) of chlorosulfonyl isocyanate was added dropwise to the mixture over 1 hour through the dropping funnel. After completion of addition, the mixture was stirred 25° C. for 1 hour.

### (Second Step)

To the thus-obtained reaction mixture, 920 g of water was added dropwise through the dropping funnel over 1 hour. After completion of addition, the resultant mixture was stirred at 25° C. for 22 hours.

### (Separation and Purification Step)

Then, 3000 g of ethyl acetate was added to the contents of the flask, and the mixture was stirred for 15 minutes. The resultant mixture was allowed to stand for 15 minutes. The aqueous layer was removed, and the organic layer was washed three times with 500 g of water, to thereby isolate a washed organic layer. The thus-obtained organic layer was concentrated under reduced pressure. Subsequently, 190 g of ethyl acetate and 760 g of toluene were added to the residue, and the inside temperature of the flask was elevated to 60° C. Subsequently, the contents of the flask were cooled to −30° C., and the precipitated crystals were recovered through filtration. The wet crystals were dried under reduced pressure, to thereby obtain 360 g (1.285 mol; yield: 66.0%) of 3-carbamoyloxyadamantan-1-yl methacrylate represented by the following formula.

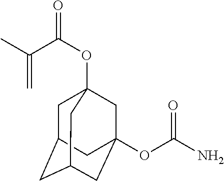 [SMILES: C=C(C)C(=O)OC12CC3CC(CC(OC(N)=O)(C3)C1)C2]

¹H-NMR (400 MHz, CDCl₃, TMS, ppm) δ: 6.24 (1H, m), 5.97 (1H, m), 5.20 (1H, br), 3.09 (1H,$), 2.90 (1H,$), 2.77 (1H, m), 1.86 (1H, m), 1.42 (1H, m), 1.35 (9H,$), 1.39-1.30 (2H, m)

### Example 2

### Synthesis of Polymer (a)

To a three-necked flask having a capacity of 50 mL and equipped with an magnetic stirrer, a reflux condenser, and a thermometer, 3.5 g (15.1 mmol) of 2-methacryloyloxy-2-methyladamantane, 1.0 g (4.3 mmol) of 3-hydroxyadamantan-1-yl methacrylate, 3.3 g (15.1 mmol) of 5-methacryloyloxy-2,6-norbornane carbolactone, 2.4 g (8.6 mmol) of 3-carbamoyloxyadamantan-1-yl methacrylate obtained in Example 1, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 8.0 g of polymer (a) having the below-described repeating units (each numerical value represents a mole fraction). The polymer (a) was found to have a weight average molecular weight (Mw) of 7,300 and a molecular weight distribution of 1.8.

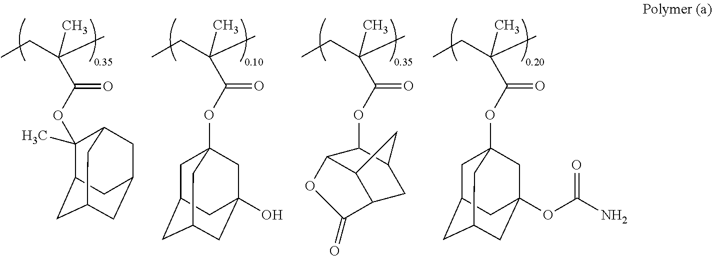

### Example 3

### Synthesis of Polymer (b)

To a three-necked flask having a capacity of 50 mL and equipped with an magnetic stirrer, a reflux condenser, and a thermometer, 3.6 g (15.5 mmol) of 2-methacryloyloxy-2-methyladamantane, 1.2 g (5.2 mmol) of 3-hydroxyadamantan-1-yl methacrylate, 3.8 g (14.6 mmol) of 5-methacryloyloxy-2,6-norbornanesultone, 2.2 g (7.7 mmol) of 3-carbamoyloxyadamantan-1-yl methacrylate obtained in Example 1, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 7.6 g of polymer (b) having the below-described repeating units (each numerical value represents a mole fraction). The polymer (b) was found to have an Mw of 8,200 and a molecular weight distribution of 1.7.

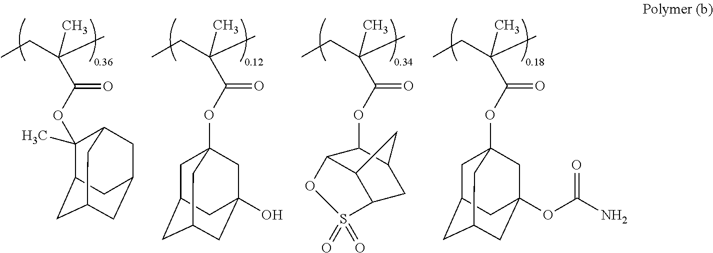

### Example 4

### Synthesis of Polymer (c)

To a three-necked flask having a capacity of 50 mL and equipped with an magnetic stirrer, a reflux condenser, and a thermometer, 3.4 g (14.6 mmol) of 2-methacryloyloxy-2-methyladamantane, 1.1 g (4.7 mmol) of 3-hydroxyadamantan-1-yl methacrylate, 4.6 g (14.6 mmol) of 5-(2′-methacryloyloxyacetyl)-2,6-norbornanesultone, 2.5 g (9.0 mmol) of 3-carbamoyloxyadamantan-1-yl methacrylate obtained in Example 1, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 8.3 g of polymer (c) having the below-described repeating units (each numerical value represents a mole fraction). The polymer (c) was found to have an Mw of 8,800 and a molecular weight distribution of 1.9.

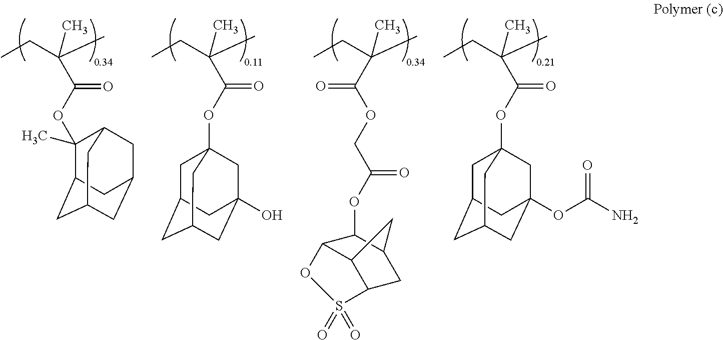

### Referential Example 1

### Synthesis of Polymer (d)

To a three-necked flask having a capacity of 50 mL and equipped with an magnetic stirrer, a reflux condenser, and a thermometer, 4.0 g (17.2 mmol) of 2-methacryloyloxy-2-methyladamantane, 1.4 g (6.0 mmol) of 3-hydroxyadamantan-1-yl methacrylate, 4.4 g (19.8 mmol) of 5-methacryloyloxy-2,6-norbornane carbolactone, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 7.3 g of polymer (d) having the below-described repeating units (each numerical value represents a mole fraction). The polymer (d) was found to have a weight average molecular weight (Mw) of 8,600 and a molecular weight distribution of 1.9.

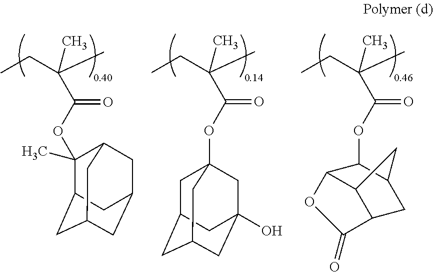

### Referential Example 2

### Synthesis of Polymer (e)

To a three-necked flask having a capacity of 50 mL and equipped with an magnetic stirrer, a reflux condenser, and a thermometer, 4.2 g (18.1 mmol) of 2-methacryloyloxy-2-methyladamantane, 1.3 g (5.6 mmol) of 3-hydroxyadamantan-1-yl methacrylate, 5.0 g (19.4 mmol) of 5-methacryloyloxy-2,6-norbornanesultone, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 7.3 g of polymer (e) having the below-described repeating units (each numerical value represents a mole fraction). The polymer (e) was found to have a weight average molecular weight (Mw) of 8,800 and a molecular weight distribution of 1.8.

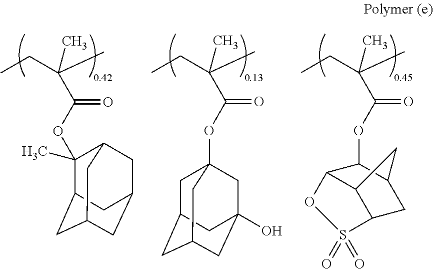

### Referential Example 3

### Synthesis of Polymer (f)

To a three-necked flask having a capacity of 50 mL and equipped with an magnetic stirrer, a reflux condenser, and a thermometer, 3.9 g (16.8 mmol) of 2-methacryloyloxy-2-methyladamantane, 1.5 g (6.5 mmol) of 3-hydroxyadamantan-1-yl methacrylate, 6.3 g (19.8 mmol) of 5-(2′-methacryloyloxyacetyl)-2,6-norbornanesultone, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 7.3 g of polymer (f) having the below-described repeating units (each numerical value represents a mole fraction). The polymer (f) was found to have a weight average molecular weight (Mw) of 8,300 and a molecular weight distribution of 1.8.

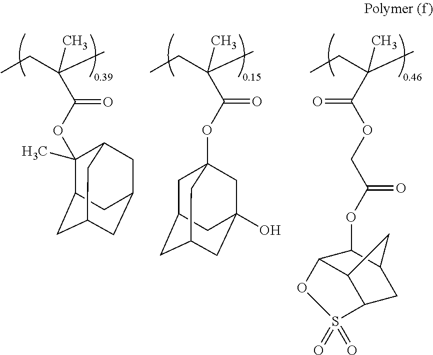

### Referential Example 4

### Synthesis of Polymer (g)

To a three-necked flask having a capacity of 50 mL and equipped with an magnetic stirrer, a reflux condenser, and a thermometer, 3.3 g (14.2 mmol) of 2-methacryloyloxy-2-methyladamantane, 1.2 g (5.2 mmol) of 3-hydroxyadamantan-1-yl methacrylate, 3.5 g (15.9 mmol) of 5-methacryloyloxy-2,6-norbornane carbolactone, 2.4 g (7.7 mmol) of 3-N,N-dimethylcarbamoyloxyadamantan-1-yl methacrylate, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 8.1 g of polymer (g) having the below-described repeating units (each numerical value represents a mole fraction). The polymer (g) was found to have a weight average molecular weight (Mw) of 8,800 and a molecular weight distribution of 1.9.

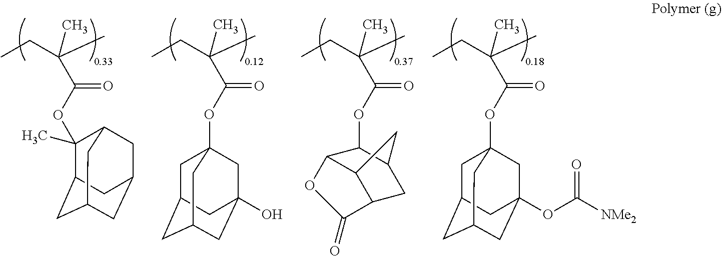

### Referential Example 5

### Synthesis of Polymer (h)

To a three-necked flask having a capacity of 50 mL and equipped with an magnetic stirrer, a reflux condenser, and a thermometer, 3.5 g (15.1 mmol) of 2-methacryloyloxy-2-methyladamantane, 1.3 g (5.6 mmol) of 3-hydroxyadamantan-1-yl methacrylate, 3.7 g (14.2 mmol) of 5-methacryloyloxy-2,6-norbornanesultone, 2.5 g (8.2 mmol) of 3-N,N-dimethylcarbamoyloxyadamantan-1-yl methacrylate, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 8.3 g of polymer (h) having the below-described repeating units (each numerical value represents a mole fraction). The polymer (h) was found to have a weight average molecular weight (Mw) of 9,000 and a molecular weight distribution of 1.8.

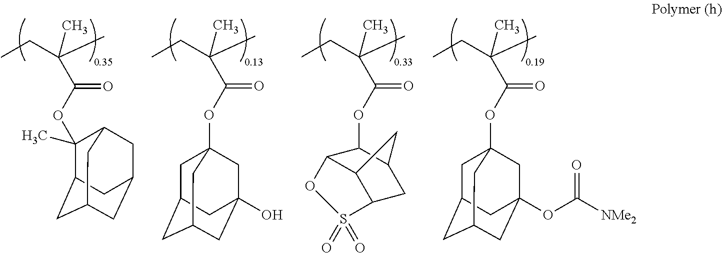

### Referential Example 6

### Synthesis of Polymer (i)

To a three-necked flask having a capacity of 50 mL and equipped with an magnetic stirrer, a reflux condenser, and a thermometer, 3.3 g (14.2 mmol) of 2-methacryloyloxy-2-methyladamantane, 1.2 g (5.2 mmol) of 3-hydroxyadamantan-1-yl methacrylate, 4.6 g (14.6 mmol) of 5-(2′-methacryloyloxyacetyl)-2,6-norbornanesultone, 2.8 g (9.0 mmol) of 3-N,N-dimethylcarbamoyloxyadamantan-1-yl methacrylate, and 36.4 g of methyl ethyl ketone were added, and nitrogen bubbling was carried out for 10 minutes.

Under nitrogen atmosphere, 0.36 g (2 mmol) of 2,2′-azobisisobutyronitrile was added to the flask, and polymerization reaction was carried out at 80° C. for 4 hours.

The resultant reaction mixture was added dropwise to 220 g of methanol at room temperature under stirring, and the obtained precipitate was separated through filtration. The precipitate was dried under reduced pressure (26.7 Pa) at 50° C. for 7 hours, to thereby obtain 8.0 g of polymer (i) having the below-described repeating units (each numerical value represents a mole fraction). The polymer (i) was found to have a weight average molecular weight (Mw) of 9,200 and a molecular weight distribution of 1.9.

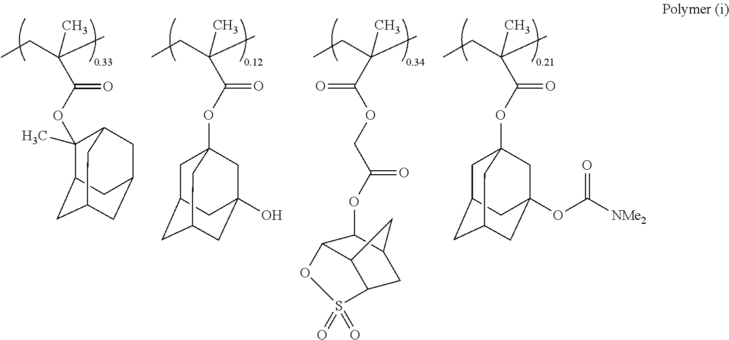

### Examples 5 to 7 and Comparative Examples 1 to 6

100 Parts by mass of each of the polymers (a), (b), (c), (d), (e), (f), (g), (h), and (i) obtained in Examples 2 to 4 and Referential Examples 1 to 6 was mixed with 4.5 parts by mass of “TPS-109” (trade name, component: triphenylsulfonium nonafluoro-n-butanesulfonate, product of Midori Kagaku Co., Ltd.) serving as a photoacid generator, and 1896 parts by mass of a solvent mixture of propylene glycol monomethyl ether acetate/cyclohexanone (1:1 by mass) serving as a solvent. Thus, nine photoresist compositions were prepared.

Each photoresist composition was separated through filtration with a membrane filter having a pore size of 0.2 μm. 6 Mass % solution of cresol novolac resin (“PS-6937,” product of Gunei Chemical Industry Co., Ltd.) in propylene glycol monomethyl ether acetate was coated onto a silicon wafer having a diameter of 10 cm through spin coating, and then baking was carried out on a hot plate at 200° C. for 90 seconds, to thereby form, on the wafer, an anti-reflection film (underlayer) having a thickness of 100 nm. The above-obtained filtrate was coated onto the wafer having the film thereon through spin coating, and prebaking was carried out on a hot plate at 130° C. for 90 seconds, to thereby form a resist film having a thickness of 300 nm. The resist film was subjected to two-beam interference exposure with ArF excimer laser having a wavelength of 193 nm. Subsequently, post-exposure baking was carried out at 130° C. for 90 seconds, and then the resultant wafer was developed with 2.38 mass % aqueous tetramethylammonium hydroxide solution for 60 seconds, to thereby form a 1:1 line and space pattern. The thus-developed wafer was cut and observed under a scanning electron microscope (SEM). There was observed the shape of the pattern with respect to exposure light for forming a 1:1 line and space having a line width of 100 nm. Also, line width roughness (hereinafter referred to as LWR) was determined. For determination of LWR, line widths were measured at a plurality of points in a measurement monitor, and the variance (3σ) of the line widths at the points was employed as an index. The shape of a cross section profile of the pattern-formed layer was observed under a scanning electron microscope (SEM) and evaluated as follows. When the patterned cross section shape had high squareness, rating “excellent” was assigned, whereas when the patterned cross section shape had low squareness, rating “poor” was assigned. The results are shown in Tables 1 and 2.

### Comparative Example 7

100 Parts by mass of the polymer (d) produced in Referential Example 1 was mixed with 4.5 parts by mass of “TPS-109” (trade name, component: triphenylsulfonium nonafluoro-n-butanesulfonate, product of Midori Kagaku Co., Ltd.) serving as a photoacid generator, 0.2 parts by mass of N-t-butoxycarbonyl-1-adamantylamine (nitrogen-containing organic compound), and 1896 parts by mass of a solvent mixture of propylene glycol monomethyl ether acetate/cyclohexanone (1:1 by mass) serving as a solvent, to thereby prepare a photoresist composition.

The photoresist composition was separated through filtration with a membrane filter having a pore size of 0.2 μm. 6 Mass % solution of cresol novolac resin (“PS-6937,” product of Gunei Chemical Industry Co., Ltd.) in propylene glycol monomethyl ether acetate was coated onto a silicon wafer having a diameter of 10 cm through spin coating, and then firing was carried out on a hot plate at 200° C. for 90 seconds, to thereby form, on the wafer, an anti-reflection film (underlayer) having a thickness of 100 nm. The above-obtained filtrate was coated onto the wafer having the film thereon through spin coating, and prebaking was carried out on a hot plate at 130° C. for 90 seconds, to thereby form a resist film having a thickness of 300 nm. The resist film was subjected to two-beam interference exposure with ArF excimer laser having a wavelength of 193 nm. Subsequently, post-exposure baking was carried out at 130° C. for 90 seconds, and then the resultant wafer was developed with 2.38 mass % aqueous tetramethylammonium hydroxide solution for 60 seconds, to thereby form a 1:1 line and space pattern. The thus-developed wafer was cut and observed under a scanning electron microscope (SEM). There was observed the shape of the pattern with respect to exposure light for forming a 1:1 line and space having a line width of 100 nm. Also, line width roughness (hereinafter referred to as LWR) was determined. For determination of LWR, line widths were measured at a plurality of points in a measurement monitor, and the variance (3σ) of the line widths at the points was employed as an index. The shape of a cross section profile of the pattern-formed layer was observed under a scanning electron microscope (SEM) and evaluated as follows. When the patterned cross section shape had high squareness, rating “excellent” was assigned, whereas when the patterned cross section shape had low squareness, rating “poor” was assigned. The results are shown in Table 2.

TABLE 1
Evaluation by exposure

| | | LWR | Pattern |
|---|---|---|---|
| | Polymer employed | (nm) | shape |
| Example 5 | Polymer (a) | 5.8 | excellent |
| Example 6 | Polymer (b) | 5.6 | excellent |
| Example 7 | Polymer (c) | 6.1 | excellent |

TABLE 2
Evaluation by exposure

| | | LWR | |
|---|---|---|---|
| | Polymer employed | (nm) | Pattern shape |
| Comp. Ex. 1 | Polymer (d) | 8.1 | excellent |
| Comp. Ex. 2 | Polymer (e) | 7.6 | excellent |
| Comp. Ex. 3 | Polymer (f) | 7.5 | excellent |
| Comp. Ex. 4 | Polymer (g) | 7.8 | poor |
| Comp. Ex. 5 | Polymer (h) | 7.5 | poor |
| Comp. Ex. 6 | Polymer (i) | 7.6 | poor |
| Comp. Ex. 7 | Polymer (d) | 8.1 | poor |
| | (+ N-containing organic | | |
| | compound) | | |

As is clear from the aforementioned data, a resist composition produced from the carbamoyloxyadamantane derivative (1) of the present invention realizes formation of a resist pattern having a favorable shape and improved LWR, as compared with the case of a resist composition not produced from the carbamoyloxyadamantane derivative (1). Meanwhile, LWR is preferably 8 nm, which corresponds 8% of a line width of 100 nm, or less. The photoresist composition of the present invention realizes a remarkably improved LWR of 7 nm or less, furthermore, 6 nm or less.

In Comparative Examples 4 to 6, employed was a polymer produced from, as a raw material, a similar carbamoyl compound in which each of the two hydrogen atoms of the carbamoyl group are substituted by a methyl group, instead of the carbamoyloxyadamantane derivative (1). In Comparative Examples 4 to 6, LWR was not satisfactorily reduced, and the pattern shape was unsatisfactory.

As is clear from the aforementioned data, a resist composition containing a polymer produced through polymerization of a raw material containing the carbamoyloxyadamantane derivative (1), realizes formation of a resist pattern having a favorable shape and considerably improved LWR, as compared with the case of a resist composition containing each of the polymers produced through polymerization of a raw material not containing the carbamoyloxyadamantane derivative (1) of the present invention.

### INDUSTRIAL APPLICABILITY

The carbamoyloxyadamantane derivative (1) of the present invention is useful as a raw material of a polymer for a resist composition which realizes formation of a resist pattern having a favorable shape and improved LWR.

1. A carbamoyloxyadamantane derivative represented by the following formula (1): 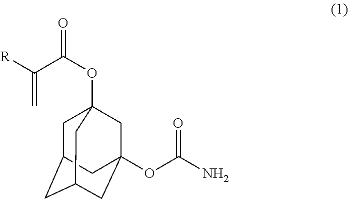
wherein R represents a hydrogen atom, a methyl group, or a trifluoromethyl group.

2. A polymer produced by polymerizing a raw material containing a carbamoyloxyadamantane derivative as recited in claim 1.

3. A photoresist composition comprising a polymer as recited in claim 2, a photoacid generator, and a solvent.
